(19) United States
(12) Patent Application Publication
(10) Pub. No.: US 2023/0304139 A1
(43) Pub. Date: Sep. 28, 2023

(54) METHODS FOR APPLYING DECORATIVE METAL FILMS ON POLYMERIC SURFACES

(71) Applicants: VERGASON TECHNOLOGY, INC., Van Etten, NY (US); HELIOS COATINGS, INC., Canton, OH (US)

(72) Inventors: Marshall E. LEININGER, Canton, OH (US); Joshua B. SOPER, Candor, NY (US)

(21) Appl. No.: 18/189,304

(22) Filed: Mar. 24, 2023

Related U.S. Application Data
(60) Provisional application No. 63/323,673, filed on Mar. 25, 2022.

(51) Int. Cl. C23C 14/16; C23C 14/02; B05D 1/00; C23C 14/34; C23C 14/32

(52) U.S. Cl. CPC C23C 14/165; C23C 14/024; B05D 1/62; C23C 14/34; C23C 14/325

(57) ABSTRACT

A method is disclosed for enhancing adhesion of a decorative metal layer to a polymeric primer that is a film on the surface of a substrate produced by a low-temperature cure. Substrates to which the polymeric primer is applied include metal, plastic or carbon fiber. The polymeric primer layer is treated with a plasma enhanced chemical vapor deposition to form a polysiloxane bonding interface layer to enhance the surface of the polymer primer layer to increase adhesion of the decorative metal layer deposited without the need for the use of specially made primers specifically made for the reception of metal layers applied physical vapor deposition.

This application claims priority to and any other benefit of U.S. Provisional Patent Application Ser. No. 63/323,673 filed Mar. 25, 2022, the contents of which are incorporated herein in their entirety by reference.

### TECHNICAL FIELD

The present invention relates to a method of applying a decorative metal film or layer to a metal, plastic or carbon fiber substrate to enhance its aesthetic appearance. More specifically, the present invention relates to an environmentally sound and inexpensive method of coating a substrate that is intended to provide a desired aesthetic appearance such as a metallic sheen closely resembling traditional plating processes without using coatings specifically formulated for a physical vapor deposition (PVD) process that add additional layers and cost to the final product.

### BACKGROUND

It is well known to apply paints, metal film layers or other types of coatings to substrates in order to provide the component with a particular aesthetic appearance. For example, in the automotive industry it is desirable to provide certain components, such as trim pieces and wheels, with a chrome-like appearance. This is especially true for post-purchase vehicle enhancements.

In order to provide a substrate or component with the desired aesthetic appearance paints and thin metal film layers are applied in sequence as one of a number of coatings on the substrate. The coatings include base layers, an appearance-creating coating and a top protective cover coat. The top protective coating is applied over the other coatings to protect them from environmental damage during use such as chipping, scratching, and corrosion. In some instances, the top protective coat may be enhanced with certain additive materials to create further desired aesthetic appearances.

A problem that is faced by the industry of applying a decorative metal layer by a physical vapor deposition process (PVD) to substrates such as automotive wheels has been the requirement to utilize a sub-coating or primer that is specifically formulated to the acceptance of the PVD-applied metal layer. These PVD, process-specific materials are custom made and are traditionally more costly than sub-coatings commonly used as a base for color paint layers. The applicator is also tasked to ensure that the layers of a layering system are properly matched to provide not only the desired aesthetic appearance but that it is able to meet desired performance specifications for the component application such as adhesion.

Known coating processes that use the sub-coatings designed for PVD-applied layers are in response to existing technology using an epoxy- or photo-cured base layer on which the metal layer is applied directly. This process has production limitations in the cure time and temperature required that may exclude some types of substrates.

The most used PVD deposition of decorative layers on automotive wheels uses an epoxy powder (e.g., Akzo Nobel Valophene™) base coat for smoothing the metal substrate that must be cured at high (>480° F.) temperature, which is over the 400° F. threshold for tempered cast aluminum wheels that are considered the primary market for the PVD deposition process of applying decorative layers. Additionally, in most automotive wheel cases, the epoxy prime coat is not economically feasible to strip should the prime coating or final finish have defects, therefore current market practice utilizes the epoxy prime coat layered over a polyester hybrid powder coating allowing the aluminum wheel to be recovered economically without having to scrap the wheel. In addition, the cure of the epoxy PVD primer cures at a temperature far exceeding the accepted bake temperature of the polyester hybrid base layer causing embrittlement and potential field failure due to objects impacting the wheel face. With the addition of a thermoset powder topcoat the potential for failure is exacerbated by yet another bake cycle. Additional art currently utilized in the field is a photo-curable tie coating over thermoset powder sub-coatings commonly used as a base primer which allows the PVD metallization layer to adhere to the tie coat surface with a powder thermoset coating commonly used as a topcoat. This tie coat adds additional complexity to achieve a smooth surface due to the additional layers of coating needed to be applied and has a significant dwell time required prior to photo initiation causing increased cost to the metallization process.

### SUMMARY

In a first aspect, disclosed is a process of applying a metal layer on a substrate, the process includes, and can be limited to, the steps of providing a substrate, the substrate having a surface, the surface of the substrate being coated with a polymeric primer layer; treating the polymeric primer layer coated on the surface of the substrate with a plasma enhanced chemical vapor deposition (PECVD) process to form a receptive bonding interface layer; applying a metal layer onto the bonding interface layer; and optionally applying a topcoat layer onto the metal layer (see FIG. 1).

In one example of aspect 1, the polymeric primer layer provides a protective and leveling coating on the surface of the substrate and the applied polymeric primer layer is cured on the substrate for a duration of 15 to 60 minutes and then cooled, for example, before applying a PECVD step to the surface of the primer layer for depositing the polysiloxane bonding interface layer directly on the surface of the polymeric primer layer.

In another example of aspect 1, the plasma enhanced chemical vapor deposition process step includes igniting a plasma utilizing a purge gas selected from the group consisting of hydrogen, oxygen, argon, and any combination thereof. The purge gas surrounds the substrate in a PECVD reactor or chamber, for example, oxygen to help form a polysiloxane when an organosilicon material (e.g., HMDSO) is introduced as a reactant.

In another example of aspect 1, the plasma enhanced chemical vapor deposition process step includes using a plasma utilizing an organosilicon compound in the PECVD reactor or chamber. The organosilicon compound, as a reactant gas or material, is selected, for example, from the group consisting of octamethyltetracyclosiloxane, octamethylcyclotetrasiloxane, tetraethoxysiloxane, tetramethylcyclotetrasiloxane, hexamethyldisiloxane, hexamethylcyclotrisiloxane, tetramethyldisiloxane, divinyltetramethyldisiloxane, dimethyltetramethoxydisiloxane, tetraethoxydimethyldisiloxane, tetramethyldiethoxydisiloxane, and any combination thereof.

In another example of aspect 1, the metal layer deposited directly on or overlying the bonding interface layer on the substrate surface includes at least a material selected from the group consisting of aluminum, steel, stainless steel, titanium, nickel, chromium, alloys thereof and a combination thereof.

In another example of aspect 1, the metal layer is deposited directly on and in contact with the bonding interface layer by a physical vapor deposition method, thermal evaporation, sputtering, or cathodic arc method.

In another example of aspect 1, the topcoat layer is a polymeric layer that is a clear powder coating or liquid clear coat for providing environmental protection to the metal layer.

In another example of aspect 1, the substrate is a metal object made by a method selected from the group consisting of sheet forming, casting, extrusion, weldments, wrought form, or 3D printing.

In another example of aspect 1, the metal object is selected from the group consisting of iron, steel, aluminum, brass, zinc, magnesium, metal alloys and combinations thereof.

In another example of aspect 1, the substrate is a plastic object produced by molding, casting, extrusion, or 3D printing or other form of fabrication, and the plastic object is comprised of a polymer selected from the group consisting of acrylonitrile-butadiene-styrene, polyvinyl chloride, polyethylene terephthalate, polybutylene terephthalate, polypropylene, polyethylene, polycarbonate, polystyrene, polyamides, acrylic or polymethyl methacrylate, and a combination thereof.

In another example of aspect 1, the substrate is a carbon fiber object produced by molding, 3D printing or other form of fabrication.

In another example of aspect 1, the substrate prepared by the process of aspect 1 or its examples can include a component, for example a vehicle component, that includes the substrate.

In a second aspect, there is disclosed a process for metalizing a substrate, said process includes, or is limited to, the following steps: providing a substrate; cleaning or preparing a surface of the substrate, the cleaning or preparing includes at least one alkaline cleaning step, one surface conversion step, a rinsing step, a sealing step, and a drying step; applying and curing a polymeric primer layer over said cleaned or prepared surface of said substrate; applying a plasma enhanced chemical vapor deposition (PECVD) layer over the polymeric primer layer to form a bonding interface layer; applying a metal layer via a sputtering, cathodic arc or thermal evaporative deposition process onto the bonding interface layer; and optionally applying and curing a topcoat layer over the metal layer, for example, see FIG. 2.

In an example of aspect 2, the polymeric primer layer is an organic, thermosetting liquid or powder which is cured at temperature in the range of 170 to 500° F.

In another example of aspect 2, the PECVD process includes the use of a purge gas selected from the group consisting of argon, oxygen, hydrogen, and any combination thereof.

In another example of aspect 2, the PECVD process includes the use of an organosilicon compound as a reactant. The organosilicon compound, as a reactant gas or material, is selected, for example, from the group consisting of octamethyltetracyclosiloxane, octamethylcyclotetrasiloxane, tetraethoxysiloxane, tetramethylcyclotetrasiloxane, hexamethyldisiloxane, hexamethylcyclotrisiloxane, tetramethyldisiloxane, divinyltetramethyldisiloxane, dimethyltetramethoxydisiloxane, tetraethoxydimethyldisiloxane, tetramethyldiethoxydisiloxane, and any combination thereof.

In another example of aspect 2, the topcoat layer includes decorative particles as an appearance-enhancing additive to further alter the aesthetic effect of the metal layer.

In another example of aspect 2, a component includes a finished substrate having a decorative metal finish, the finished substrate prepared by the process of aspect 2.

In a third aspect, there is disclosed an automotive component substrate having a coating overlying its surface that consists of a polymeric primer layer directly on the substrate surface, a PECVD-deposited, oxygenated polysiloxane bonding interface layer directly contacting the polymeric primer layer, a metal layer directly contacting the bonding interface layer and a topcoat layer overlying the metal layer.

In an example of aspect 3, the automotive component substrate is a metal vehicle wheel.

In another example of aspect 3, the PECVD-deposited, oxygenated polysiloxane bonding interface layer is deposited by using an oxygen purge gas and an organosilicon compound, as a reactant gas or material, which is selected from the group consisting of octamethyltetracyclosiloxane, octamethylcyclotetrasiloxane, tetraethoxysiloxane, tetramethylcyclotetrasiloxane, hexamethyldisiloxane, hexamethylcyclotrisiloxane, tetramethyldisiloxane, divinyltetramethyldisiloxane, dimethyltetramethoxydisiloxane, tetraethoxydimethyldisiloxane, tetramethyldiethoxydisiloxane, and any combination thereof. In one example, the organosilicon compound is hexamethyldisiloxane.

In another example of aspect 3, the bonding interface layer has a thickness in the range of 50 to 500 angstroms.

In another example of aspect 3, the polymeric primer layer is an acrylic layer, for example, a glycidyl methacrylate acrylic layer, an epoxy, a triglycidyl isocyanurate polyester, or a combination thereof.

The above aspects (or examples of those aspects) may be provided alone or in combination with any one or more of the examples of that aspect or another aspect discussed above; e.g., the first aspect may be provided alone or in combination with any one or more of the examples of the first aspect, second aspect, third aspect or other aspects discussed above.

Additional features and advantages will be set forth in the detailed description which follows, and in part will be readily apparent to those skilled in the art from that description or recognized by practicing the embodiments as described herein, including the detailed description which follows, the claims, as well as the appended drawings.

### BRIEF DESCRIPTION OF THE DRAWINGS

The present disclosure is better understood when the following detailed description is read with reference to the accompanying drawings.

FIG. 1 shows a cross-sectional view of a substrate showing the coating layers formed thereon from a process in accordance with the present invention.

FIG. 2 shows a flow diagram showing the steps of a process in accordance with the present invention.

### DETAILED DESCRIPTION

The terminology as set forth herein is for description of the embodiments only and should not be construed as limiting the invention as a whole.

Herein, when a range such as 5-25 (or 5 to 25) is given, this means preferably at least or more than 5 and, separately and independently, preferably not more or less than 25. In an example, such a range defines independently 5 or more, and separately and independently, 25 or less.

The present invention applies to a component or a prepared substrate and the process of preparing the substrate for receiving a metal layer, such as a decorative metal layer, on a surface of a substrate. The prepared substrate can be a substrate with a multi-layered coating that includes a metal layer that imparts a desired aesthetic appearance and functional properties. The substrate and process of applying the metal layer preferably eliminates a prime or base layer that is conventionally used and designed for applying a metal or decorative layer by a PVD process, or the use of a base layer that can damage the substrate or surface thereof during a heat cure treatment. The present invention, by eliminating one or more base layers that may require a cure temperature above the threshold of a particular substrate and/or the acceptable exposure temperature or bake temperature of the presence of other intermediate layers overlying the substrate surface, broadens the range of potential substrates that can be used for application of a metal layer, for example, a decorative layer applied by a PVD process. Thus, the present invention that utilizes treated polymeric primer layer can reduce damage or future defects caused by the use of conventional layers on a substrate.

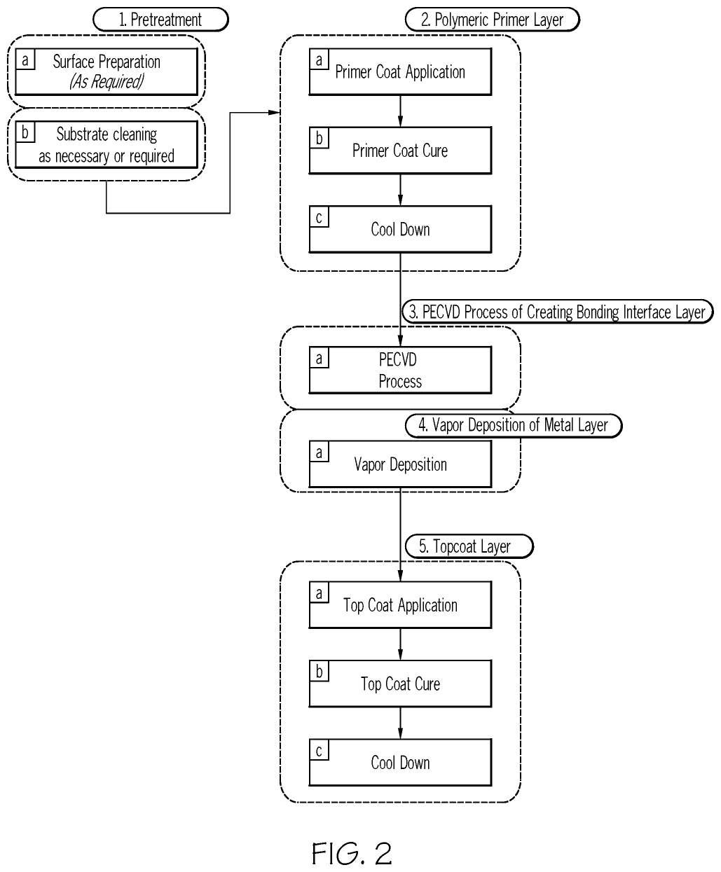

The process of preparing a substrate according to one or more embodiments of the present invention includes up to four steps, such as the process shown in FIG. 2. The process entails four primary stages including an optional cleaning or pretreatment of the substrate, application of leveling or smoothing polymer layer (i.e. polymeric primer layer) such as a thermoset powder coating to protect the substrate followed by a PECVD process for deposition of a bonding interface layer to enhance the adhesion of the PVD metal layer, a metalizing layer deposited by sputtering, cathodic arc or thermal evaporative deposition, and a final polymeric liquid or powder protective top coating. The resulting layering produces a decorative coating with interior and exterior durability qualities as required for automotive applications.

The term “substrate” refers to any material or surface to which a decorative coating is or can be applied by the methods described herein such as, without limitation, metals, thermoset polymers and other plastics, as well as composite materials and ceramics. Furthermore, the shape of the substrate and particularly the surface to be coated can be any part of an assembly or device manufactured by any of various methods, such as, without limitation, casting, molding, machining, extruding, welding, wrought, or otherwise fabricated. In one example, the substrate is a plastic object produced by molding, casting, extrusion, or 3D printing or other form of fabrication. The substrate may be of various shapes, sizes, and materials (e.g., plastic, metal, carbon fiber, etc.).

A plastic substrate, for example, can include or be made of a polymer selected from the group consisting of acrylonitrile-butadiene-styrene, polyvinyl chloride, polyethylene terephthalate, polybutylene terephthalate, polypropylene, polyethylene, polycarbonate, polystyrene, polyamides, acrylic or polymethyl methacrylate, and any combination thereof.

Metals used as substrates herein can include ferrous metals and non-ferrous metals, such as, without limitation, steel, iron, aluminum, zinc, magnesium, alloys and combinations thereof. In one embodiment, a metal substrate is formed from steel, aluminum, or aluminum alloys.

One preferred application contemplated herein is the coating of substrates that are automotive components such as wheels, bumpers and trim components such as mirrors, step rails, luggage racks, grills, door or fender panel railing and bump guards, etc. More preferably, the substrate is a steel or aluminum alloy wheel used in the automotive industry.

The term “overlies” and cognate terms such as “overlying” and the like, when referring to the relationship of one or a first, superjacent layer relative to another or a second, subjacent layer, means that the first layer partially or completely lies over the second layer. The first, superjacent layer overlying the second, subjacent layer may or may not be in contact with the subjacent layer; one or more additional layers may be positioned between respective first and second, or superjacent and subjacent, layers.

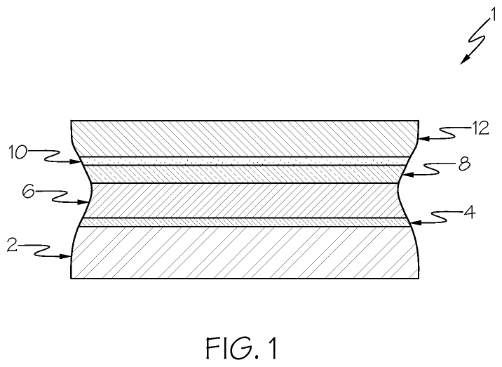

With reference to FIG. 1, there is shown a cross section of a component 1 that has a substrate 2 having a plurality of layers that include a preferred arrangement for applying a decorative metal layer 10 as discussed herein. The layer arrangement on the substrate 1 is as follows: an optional pretreatment layer 4, a polymeric primer layer 6, a bonding interface layer 8, a metal layer 10, and a topcoat layer 12. As shown in FIG. 1, the pretreatment layer 4, although optional, is applied directly onto and overlies the substrate 2, followed by the polymeric primer layer 6, which overlies the pretreatment layer 4, the bonding interface layer 8 overlies the polymeric primer layer 6, the metal layer 10 which overlies the bonding interface layer 8, and the topcoat layer 12 which overlies the metal layer 10. It is understood that the layer arrangement shown in FIG. 1 can include additional layers between, on top of or on the bottom of the layers shown. Each of the layers described above and shown in FIG. 1, as well as methods or processes for providing and depositing them, is further described below.

The pretreatment layer 4 of FIG. 1 is an optional but preferred layer. It is applied to the exposed surface of the substrate 2, for example, to inhibit future oxidation of the substrate surface and to convert the substrate surface to a uniform, inert surface that improves the bonding of the overlying applied layer, such as the polymeric primer layer 4. Typically, a pretreatment layer 4 of this type is a conversion coating as known in the art. Conversion coating materials can include, but are not limited to, phosphate, iron, zinc, chromium, manganese, or combinations thereof, which can be applied via conventional techniques. For example, such coatings may be applied via conventional spray coating techniques at a temperature of 100 to 180° F. for 60 to 120 seconds. However, other conventional, well-known methods of application can be used to apply the pretreatment layer 4 of FIG. 1.

The polymeric primer layer 6 is applied to the surface of the substrate 2, or the pretreatment layer 4 if present, to provide a smooth, level surface for the deposition of the remaining superjacent layers. The polymeric primer layer 6 significantly reduces the amount of mechanical surface preparation of the substrate 2 that will be required to ensure that surface defects will not show or be visible through the metal layer 10 once it is deposited. It should be pointed out the polymeric primer layer 6 is not necessarily considered to completely obviate or eliminate all mechanical surface preparation prior to depositing the metal layer 10. Indeed, some mechanical treatment of either the substrate 2, or of the polymeric primer layer 6 once it is applied and cured, may be desirable in particular applications. What is contemplated, however, is that the as-applied polymeric primer layer 6 surface is or will be significantly smoother than the virgin substrate surface when applied overlying the substrate 2 or pretreatment layer 4, and if additional mechanical surface treatment is to be performed, such will be of considerably lesser degree and can be achieved with less abrasive or corrosive methods and materials than conventionally used.

For example, before applying a polymeric primer layer 6, the substrate 2 can be cooled to a low temperature, preferably to a temperature below a coalescing temperature of the polymeric primer layer material to prevent premature sintering of the layer 6, which often can cause a ripple or orange peel effect on the surface of the layer, thus requiring surface preparation before the metal layer 10 is applied to the polymeric primer layer 6. Furthermore, defects in the polymeric primer layer 6 such as pin holes, can result if the substrate 2 is not heated prior to applying the layer 6. For instance, preferably, the substrate 2 is heated to 220 to 350° F. after the pretreatment layer 4 is applied to release any trapped gas before the substrate 2 and pretreatment layer 4 are cooled to ambient temperature for application of the polymeric primer layer 6. If the pretreatment layer 4 is not applied, it is also preferred to heat the substrate 2 in a similar manner as described above before applying the polymeric primer layer 6. Such defects should be reworked prior to depositing the metal layer 10, but will require less rigorous, time, cost and labor intensive methods than conventional surface preparations for virgin substrates.

The polymeric primer layer can be cured using thermal, air dry, photo or any chemical reactant polymerization methods. It is preferable that the polymeric primer layer 6 is composed of a material that can be thermally cured, for example, at a temperature of 275 to 375° F., and more preferably at 300 to 330° F. The polymeric primer layer 6 can be deposited as a thermally-curable material, preferably a thermoset powder coating composition, that cures when exposed to heat, less preferably to a combination of heat and radiation. Powder coating compositions are comprised of a film forming material or binder as a main component and, optionally, a pigment. The amount of film forming material in the powder coating composition generally ranges from about 50% to 97% by weight of the powder coating composition. Acceptable film forming binder materials include but are not limited to epoxy resin, epoxy-polyester resin, polyester resin, acrylic resin, acryl-polyester resin, fluororesin and the like. Of those noted, an acrylic resin is preferable to provide superior anti-weathering capability and corrosion protection, as is required for automotive component, such as wheels. In addition, when thermosetting resins are used as the film forming material, a curing agent also is used. Suitable curing agents may be those known according to the functional group aligned and compatible with the thermosetting resin to be used to initiate and promote cross-linking thereof. Useful curing agents depending on the target functional groups include block isocyanate, aliphatic polycarboxylic acid, aliphatic anhydride, aminoplast resin, triglycidyl isocyanate, hydroxyalkylamide, phenol resin, polyisocyanates, polyacids, polyanhydrides, dodecanedioic acid and mixtures thereof. The amount of curing agent in the powder coating composition generally ranges from about 3% to 50%, by weight. Powder coating compositions can further comprise one or more pigments or other additives such as an ultraviolet absorber, rheology control agent, antioxidant, pigment dispersing agent, fluidizing agent, surface adjusting agent, foam inhibitor, plasticizer, charge inhibitor, surfactant or the like. In an example embodiment the average particle size of the powder coating particles is about 10 μm to 30 μm, preferably about 15 μm to 25 μm and more preferably about 18 μm. It is preferred that the polymeric primer layer 6 be a resin-based product, for example, a product that is a clear, colorless acrylic resin.

The polymeric primer layer 6 can be applied over the surface of the substrate 2 or of an intermediate layer, such as the pretreatment layer 4 if present, by any of the well-know and conventional methods such as electrostatic spraying, frictional electrification, spraying and fluidized bed.

The polymeric primer layer 6 preferably is a thermally-cured layer that can be cured by any of the well-known and conventional heating methods. Preferably, the polymeric primer layer 6 is pre-cured by heating the substrate 2 and applied polymeric primer layer 6, as well as any intermediate layers, from ambient temperature, at which the polymeric primer layer 6 is initially deposited, to approximately 250 to 290° F., for instance, via a temperature rise rate of 30 to 80° F. per minute, or more preferably 40 to 60° F. per minute. It is preferred that the substrate 2 and polymeric primer layer 6 be maintained at approximately 250 to 290° F. for 1 to 12 minutes, and more preferably at approximately 265 to 275° F. for 4 to 8 minutes. Subsequent to the pre-cure, the substrate 2 and polymeric primer layer 6 are baked at a temperature of approximately 260 to 375° F. for a period of 10 to 45 minutes. It is preferred that the substrate 2 and polymeric primer layer 6 are baked at approximately 290 to 325° F. for 25 to 35 minutes. Finally, the substrate 2 and polymeric primer layer 6 are cooled to approximately 100 to 200° F., more preferably to approximately 140 to 170° F., prior to treating for the next overlying bonding interface layer 8.

Proper cure of the coating can be measured by a variety of methods known to the industry, such as Differential Scanning Calorimetry, multiple rub with methyl ethyl ketone, dye stain and pencil hardness.

The polymeric primer layer 6 has a dry or cured thickness at least effective to significantly level out the surface of the substrate 2. Generally, this thickness is from 10 μm to 100 μm, preferably from 20 μm to 80 μm, more preferably from 30 μm to 75 μm and even more preferably from about 40 μm to about 65 μm.

As shown in FIG. 1, overlying the polymeric primer layer 6, for example a cured polymeric primer layer, is a bonding interface layer 8. The bonding interface layer 8 is applied onto the polymeric primer layer by plasma enhanced chemical vapor deposition, or PECVD, which is a process of depositing a thin layer or film onto a substrate at a temperature (e.g., room temperature to 350° C.) that can be lower than chemical vapor deposition. In the present case, use of lower temperatures achievable with PECVD, for example in a PECVD reactor, which can take many different forms, to deposit the bonding interface layer 8 protects the substrate and other underlying layers from being exposed to potentially damaging higher temperatures. There is also less stress caused between the substrate and overlying layers at lower temperatures, for example, stress that can be caused by varying thermal expansion and contraction coefficients.

The depositing of the bonding interface layer 8 on the substrate is carried out in a deposition chamber. Generally, a PECVD reactor will include at least one, or more, chamber that enclose the substrate for processing. Multiple substrates can be processed as desired.

The substrate 2 coated with at least the polymeric primer layer 6, and optionally with the pretreatment layer 4 if present, is heated, for example, the coated substrate 2 can be heated on a heated platform or pedestal (e.g., an electrostatic chuck, a resistively heated pedestal or other types available in the industry). The substrate coated with one or more layer (e.g., 4, 6) is heated in the deposition chamber to a temperature in the range of 25° to 400° C., 50° to 350° C., 100° to 325° C., or 150° to 300° C. A substrate soak time can be adjusted as needed to ensure the substrate is at the desired steady-state temperature. A purge gas can be supplied to the deposition chamber, either before, during or after heating of the substrate. The purge gas for the PECVD process step for depositing the bonding interface layer 8 can be, for example, hydrogen, oxygen, ozone, argon, helium, carbon dioxide, nitrous oxide or nitrogen, or any combination of these gases. In one embodiment, the purge gas is only oxygen. The purge gas may be free of the reactant process gas or material being delivered in the PECVD process, for example, to a deposition chamber. Purge gas is introduced into the deposition chamber, for example, at a flow rate of 50 to 500 standard cubic centimeters per minute (sccm), 75 to 400 sccm, 100 to 300 sccm or 150 to 250 sccm. Pressure of the purge gas can be any suitable range, for instance, 1 to 100 mTorr, 3 to 50 mTorr or 5 to 25 mTorr.

The reactant gas or material for the PECVD process step for depositing the bonding interface layer 8 can be, for example, an organosilicon compound. In one or more embodiments, the reactant gas or material can be octamethyltetracyclosiloxane, octamethylcyclotetrasiloxane, tetraethoxysiloxane, tetramethylcyclotetrasiloxane, hexamethyldisiloxane, hexamethylcyclotrisiloxane, tetramethyldisiloxane, divinyltetramethyldisiloxane, dimethyltetramethoxydisiloxane, tetraethoxydimethyldisiloxane, tetramethyldiethoxydisiloxane, or any combination thereof. In one embodiment, the reactant material is only hexamethyldisiloxane. Reactant gas or material is introduced into the deposition chamber, for example, at a flow rate of 5 to 200 standard cubic centimeters per minute (sccm), 10 to 150 sccm, 15 to 100 sccm or 20 to 50 sccm.

To facilitate deposition of material onto the surface of the polymeric primer layer 6, the process includes igniting a plasma in the deposition chamber. The plasma ignites wherein the reactant gas or material react and cause deposition of a silicon material on the surface of the polymeric primer layer 6. The silicon material can be a silicon oxide or dioxide, for example, SiOₓ or a polysiloxane such an oxygenated polysiloxane. Pressure in the deposition chamber can be any suitable range, for instance, 1 to 100 mTorr, 3 to 80 mTorr, 5 to 50 mTorr, or 10, 15, 20, 25, 30, 35, 40 or 45 mTorr.

The deposition may last for a desired period of time, for instance, between 1 and 40 seconds, 5 to 35 seconds, 10 to 30 seconds, or 15, 20, 25 or 30 seconds, depending on the rate of deposition and thickness of the bonding interface layer 8. The applied AC plasma frequency during the depositing of the bonding interface layer can be in the range of 10 to 100 kHz, 20 to 80 kHz, or 30, 40, 50, 60 or 70 kHz. The applied power during the depositing of the bonding interface layer can be in the range of 1 to 20 kw, 2 to 18 kw, 3 to 15 kw, 4 to 12 kw or 5 to 10 kw.

The bonding interface layer 8 can be deposited at any suitable thickness, for example, layer 8 can have a general thickness of 10 to 1,500 angstroms, preferably from 50 to 1,000 angstroms, and more preferably from about 100 to about 500 angstroms. In another example, the bonding interface layer 8 has an average thickness of 50 to 500 angstroms, from 70 to 300 angstroms, from 90 to 250 angstroms, from 100 to 200 angstroms, or about 110, 120, 130, 140, 150, 160, 170, 180 or 190 angstroms.

One skilled in the art would readily note that other variations in addition to the PECVD process disclosed herein are alternative and possible for depositing a layer. After deposition of the bonding interface layer 8, the reactant gas or material is stopped. The substrate 2 coated with the bonding interface layer 8 is then processed to apply the metal layer 10.

The metal layer 10 of FIG. 1 is applied onto and overlies the bonding interface layer 8 to provide a decorative or aesthetic appearance to the substrate 2. Preferably, the metal layer 10 (e.g., a decorative metal layer) is applied over the bonding interface layer 8 in atomized form. The metal layer 10 can be applied via one of several techniques known to the industry, such as physical vapor deposition (PVD), chemical vapor deposition, magnetron sputtering and plasma deposition. Of these processes, physical vapor deposition is the most desirable in the present application having a substrate with an exposed bonding interface layer 8 adapted for a PVD coating. Each of these methods requires a target metal to be atomized, usually in a vacuum chamber, by electric charge, heating or pressurized inert gas. Atoms of the metal are carried to the surface onto which the atoms are to be deposited, and they are deposited thereon until a desired thickness is achieved. The metal layer 10 selectively adheres to the bonding interface layer 8, for example, as a decorative surface for component 1.

The metal layer 10 is preferably a continuous, uninterrupted layer which adheres directly to the bonding interface layer 8. The metal layer 10 preferably does not contain channels, etchings or other voids which allow the overlying topcoat layer to come into contact with the bonding interface layer. In certain instances, the overlying topcoat layer does not encapsulate the decorative metal layer.

Metals suitable for depositing as the metal layer 10 onto the bonding interface layer 8 include, but are not limited to, aluminum, nickel, nickel chromium alloy, aluminum chromium alloy, titanium, chromium, stainless steel, gold, platinum, zirconium, silver, combinations thereof and alloys thereof.

The metal layer 10 can be applied at any suitable thickness, for example, layer 10 can have a general thickness of 10 to 2,500 angstroms, preferably from 250 to 2,000 angstroms, and more preferably from about 300 to about 1,200 angstroms. In one embodiment, the decorative metal layer 10 has a thickness of about 250 to 400, 300 to 700, 450 to 750 or 300 to 1,000 angstroms.

The topcoat layer 12 of FIG. 1 is applied directly onto and overlies the metal layer 10, for instance, to prevent oxidation and environmental damage to the decorative nature and aesthetic appearance of the metal layer 10. In some instances, the composition of the topcoat layer 12 can be the same as that of the polymeric primer layer 6. Thus, the method of applying the topcoat layer 10 is or can be the same as that described above with respect to the leveling layer 4. For instance, because the methods of applying the polymeric primer layer 6 and the topcoat layer 12 can be the same, risk of contamination of powders or other coating materials in the processing area is minimized. Furthermore, the same booth and application equipment can be used to apply both layers, thereby reducing equipment and labor costs associated with coating the substrate 2.

It is understood that although the composition of the topcoat layer 12 can be the same as the polymeric primer layer 6, alternative compositions of the topcoat layer 12 include all those referenced herein, for example, for the polymeric primer layer 6. In one or more embodiments, the material for the topcoat layer 12 is selected from the group consisting of an acrylic or polyester thermosetting powder, a liquid thermoset material, a liquid photo-cured material or a PECVD coating.

The topcoat layer 12 has a dry or cured thickness at least effective to protect the surface of the metal layer 10, as well as the underlying layers (e.g., 4, 6, 8) and the substrate 2. Generally, this thickness of the topcoat layer 12 can be from 10 μm to 100 μm, preferably from 20 μm to 80 μm, more preferably from 30 μm to 75 μm and even more preferably from about 40 μm to about 65 μm.

In one or more embodiments, the topcoat layer (e.g., thermally cured) includes an appearance-enhancing additive to further alter the aesthetic effect of the metallic or metal layer. For instance, the topcoat layer can include decorative particles that are dispersed throughout the continuous layer. The decorative particles can be, but are not limited to, mirrors, glass, fractured glass, fractured mirrors, beads, powders, colored glass, prisms, micas, aluminum, reflective materials, metal flakes, glitter, materials that sparkle, and other particles capable of producing a specular brilliance. Decorative particles having different colors can be used to achieve a reflective coating which displays a select color combination. The decorative particles can have a particle size in the range of 1 to 100 microns, preferably 1 to 45 microns and preferably 1 to 15 microns.

The decorative particles can be pre-mixed with the uncured material (e.g., powder) used to form the composition for the topcoat layer in order to form a dry blend or powder mixture that can be applied to the metal layer on the substrate. The weight ratio of decorative particles to the uncured powder topcoat composition can be 1:99 to 99:1. The weight ratio is preferably about 1:99 to about 20:80.

The powder mixture of decorative particles and topcoat material can be applied to the metal layer by any of the well-known techniques such as spraying, electrostatic spraying and frictional electrification. The topcoat layer can be baked at the conditions described above (e.g., 260 to 375° F. for a period of 10 to 45 minutes).

FIG. 2 shows a process flow diagram that illustrates the steps of preparing the coated substrate. In an optional first step, the substrate can be prepared for applying overlying layers. In one example, the process can include a step of cleaning or preparing a surface of the substrate. The cleaning or preparing can include at least one alkaline cleaning step, one surface conversion step, a rinsing step, a sealing step, a drying step, or any combination thereof. Another optional treatment is the application of a pretreatment layer. The pretreatment layer is applied to the exposed surface of the substrate 2, for example, that has been prepared by cleaning to remove any surface imperfections or debris that may interfere with adhesion of overlying layer. A pretreatment layer can inhibit future oxidation of the substrate surface and to convert the substrate surface to a uniform, inert surface that improves the bonding of the overlying applied layer, such as the polymeric primer layer. The polymeric primer layer is applied over the substrate surface or on intermediate layer by conventional methods, cured after being applied and then cooled before the next process step.

The polymeric primer layer is treated with a PECVD process step that applies a plasma enhanced chemical vapor deposition (PECVD) layer over the polymeric primer layer to form a bonding interface layer. The bonding interface layer enhances the adhesion of the subsequent metal layer applied by a physical vapor deposition process onto the surface of the interface layer. The metal layer applied to the bonding interface layer provides the desired aesthetic appearance to the substrate. To protect the metal layer, the coated substrate can further include an optional topcoat layer, for example, that can be applied directly to the metal layer, cured by heating and then subjected to a cool down step to form a finished substrate that can be the sole part or an individual part of a component, such as a vehicle component.

### EXAMPLES

The following examples illustrate specific and exemplary embodiments and/or features of the embodiments of the present disclosure. The examples are provided solely for the purposes of illustration and should not be construed as limitations of the present disclosure. Numerous variations over these specific examples are possible without departing from the spirit and scope of the presently disclosed embodiments.

### Example 1

Aluminum alloy vehicle wheels, OEM aluminum alloy, A356, were used as substrates. The wheel substrates were subjected to a multi-step process to apply a decorative metal layer overlying a PECVD bonding interface layer. In a first step, the wheel substrates were subjected to a pretreatment process for cleaning and preparation of the substrate surface. The substrate pretreatment process is shown below in Table 1.

TABLE 1

| | | Wash | | Surface | | Blow |
|---|---|---|---|---|---|---|
| | | Deoxification | | Conversion | | Off |
| Wash | Rinse | Slight etch | Rinse | Treatment | Rinse | Dry |
| Ridolene | RO | Deoxalume | RO | Alodine 4595* | RO | Compressed |
| 412* | Water | 151* | Water | | Water | Air |
| | | | | | | Oven Dry |

*Supplied by Bonderite

After the wheel substrates were prepared, a polymeric primer layer was individually applied to a single wheel substrate surface and cured. Five different polymer primer layers were evaluated. Wheel substrates were coated with each individual polymeric primer layer to give multiple wheel substrates coated with each particular polymeric primer layer. Table 2 below shows the polymeric primer layer materials used on individual substrates.

TABLE 2

| | | | | | Polymeric |
|---|---|---|---|---|---|
| | | | | | Primer |
| Manu- | Product | | | Formu- | Thickness |
| facturer | Number | Chemistry | Color | lation | (microns) |
| Royal | EE9-1912 | Epoxy | Clear | Proprietary | 50-100 |
| Powder | | | | | |
| Coatings | | | | | |
| Protech | ACB- | GMA Acrylic | Black | Proprietary | 50-100 |
| Group | 4286 | | | | |
| Powder | | | | | |
| Coatings | | | | | |
| Akzo Nobel | QN009Q | TGIC Polyester | Black | Proprietary | 50-100 |
| Interpon | | Super Durable | | | |
| Akzo Nobel | QN014QF | TGIC Polyester | Black | Proprietary | 50-100 |
| Interpon | | Super Durable | | | |
| PPG | PCT99157 | TGIC Polyester | Black | Proprietary | 50-100 |
| | | Super Durable | | | |

*Glycidyl methacrylate (GMA)
*Tri glycidyl isocyanurate (TGIC)

For selected wheel substrates, a PECVD-deposited polysiloxane (e.g., an oxygenated polysiloxane), bonding interface layer or coating was deposited directly onto the polymeric primer layer of each wheel substrate. The PECVD coating parameters are shown below in Table 3. The bonding interface layer was deposited at room temperature.

As further shown below, the wheel substrates were compared with other wheel substrates subjected to the same process as Example 1 except without the PECVD bonding interface layer present to evaluate the bonding impact of a metal layer to the wheel substrate with and without the bonding interface layer.

TABLE 3

| | | PECVD | O₂ | AC Plasma | Applied | Coating | Coating |
|---|---|---|---|---|---|---|---|
| HMDSO | O₂ | Pressure | Pressure | Frequency | Power | Time | Thickness |
| (sscm) | (sccm) | (mTorr) | (mTorr) | (kHz) | (kw) | (sec) | (nm) |
| 20 | 200 | 20-30 | 7-10 | 40 | 6 | 20-25 | 13-15 |

*hexamethyldisiloxane (HMDSO)

The wheel substrates, all having the polymeric primer layer and some having the PECVD bonding interface layer, were coated with a metal layer. The metal layer was deposited using a sputtering method using argon as a working gas. The metal layer coating period was 25 seconds at pressure of 1.4-1.7 mTorr, and at a power of 35 kw.

TABLE 4

| | | | Metal Layer |
|---|---|---|---|
| | Product | | Thickness |
| Manufacturer | Number | Metal Composition | (Angstroms) |
| Vergason Technology, | 2520125-24 | AlCr Alloy | 300-700 |
| Inc. | | | |
| Vergason Technology, | 2520126-11 | NiCr Alloy | 300-700 |
| Inc. | | | |
| Vergason Technology, | 2520170-08 | AL 6061 | 450-750 |
| Inc. | | | |
| Vergason Technology, | 2520123-16 | Cr | 250-375 |
| Inc. | | | |
| Vergason Technology, | 2520112-14 | Ti | 300-1000 |
| Inc. | | | |

A topcoat layer was applied over the metal layer to complete the coated wheel substrates. Four different topcoat layers were applied. Table 5 below shows the topcoat layer materials used on individual substrates.

TABLE 5

| | | | | | Topcoat |
|---|---|---|---|---|---|
| | Product | | | Formu- | Thickness |
| Manufacturer | Number | Chemistry | Color | lation | (microns) |
| Royal Powder | EE9-1912 | Epoxy | Clear | Proprietary | 50-100 |
| Coatings | | | | | |
| Protech Group | ACE-2253 | GMA | Clear | Proprietary | 50-100 |
| Powder Coatings | | Acrylic | | | |
| Akzo Nobel | CZ003Q | GMA | Clear | Proprietary | 50-100 |
| Interpon | | Acrylic | | | |
| Akzo Nobel | CZ003Q | GMA | Clear | Proprietary | 50-100 |
| Interpon | | Acrylic | | | |
| PPG | PCC10103 | GMA | Clear | Proprietary | 50-100 |
| | | Acrylic | | | |

The coated wheels were further evaluated to assess the adhesion of the metal layer to the polymeric primer layer (i.e. wheel substrates without a PEVCD bonding interface layer) and the metal layer to the PECVD bonding interface layer that overlies the polymeric primer layer. Adhesion test ASTM-3359B was used to evaluate adhesion of the metal layer to underlying layer, either polymeric primer layer or PECVD bonding interface layer. The results of the evaluation are shown below in Table 6.

TABLE 6

| Polymeric | PECVD | | | | Appearance |
|---|---|---|---|---|---|
| Primer Layer | Bonding | Adhesion | Adhesion | Mechanical | Notes/ |
| (Product) | Interface Layer | ASTM3359B | Rating | Property | Rating |
| EE9-1912, | No | 4B | Pass | Good/ | Poor/hazy |
| Epoxy, Clear | | | | some | |
| Color | | | | cracking | |
| EE9-1912, | Yes - as noted | 5B | Pass | Excellent/ | Excellent |
| Epoxy, Clear | in Table 3 | | | No | |
| Color | | | | cracking | |
| ACB-4286, | No | 2B | Fail | Cracking | Poor/ |
| GMA Acrylic, | | | | | Hazy |
| Black | | | | | |
| ACB-4286, | Yes - as noted | 5B | Pass | Excellent/ | Excellent |
| GMA Acrylic, | in Table 3 | | | No | |
| Black | | | | cracking | |
| QN009Q, TGIC | No | 3B | Fail | No | Excellent |
| Polyester Super | | | | cracking | |
| Durable, Black | | | | | |
| QN009Q, TGIC | Yes - as noted | 5B | Pass | Excellent/ | Excellent |
| Polyester Super | in Table 3 | | | No | |
| Durable, Black | | | | cracking | |
| QN014QF, | No | 3B | Fail | No | Excellent |
| TGIC Polyester | | | | cracking | |
| Super Durable, | | | | | |
| Black | | | | | |
| QN014QF, | Yes - as noted | 5B | Pass | Excellent/ | Excellent |
| TGIC Polyester | in Table 3 | | | No | |
| Super Durable, | | | | cracking | |
| Black | | | | | |
| PPG, TGIC | No | 3B | Fail | Slight | Poor/hazy |
| Polyester Super | | | | cracking | |
| Durable, Black | | | | | |
| PPG, TGIC | Yes - as noted | 5B | Pass | Good/No | Very slight |
| Polyester Super | in Table 3 | | | cracking | haze, |
| Durable, Black | | | | | acceptable |

Table 6 evidences that the presence of a PECVD bonding interface layer of an oxygenated-polysiloxane material significantly improves the adhesion of the decorative metal layer to a wheel substrate as compared to the same wheel substrate having the same coating except for the absence of the PECVD bonding interface layer positioned between the polymeric primer layer and the decorative metal layer.

While various aspects and embodiments of the compositions and methods have been disclosed herein, other aspects and embodiments will be apparent to those skilled in the art. The various aspects and embodiments disclosed herein are for purposes of illustration and are not intended to be limiting, with the true scope and spirit being indicated by the claims.

1. A process of applying a metal layer on a substrate, said process:
i) providing a substrate, the substrate comprising a surface, the surface of the substrate being coated with a polymeric primer layer;
ii) treating the polymeric primer layer coated on the surface of the substrate with a plasma enhanced chemical vapor deposition (PECVD) process to form a receptive bonding interface layer;
iii) applying a metal layer directly onto the bonding interface layer; and
iv) optionally applying a topcoat layer onto the metal layer.

2. The process of claim 1, wherein said polymeric primer layer provides a protective and leveling coating on the surface of the substrate, the polymeric primer layer is cured for a duration of 15 to 60 minutes prior to depositing the bonding interface layer.

3. The process of claim 1, the plasma enhanced chemical vapor deposition process comprising a plasma utilizing a purge gas selected from the group consisting of hydrogen, oxygen, argon, and any combination thereof.

4. The process of claim 1, the plasma enhanced chemical vapor deposition process comprising a plasma utilizing an organosilicon compound.

5. The process of claim 4, the organosilicon compound selected from the group consisting of octamethyltetracyclosiloxane, octamethylcyclotetrasiloxane, tetraethoxysiloxane, tetramethylcyclotetrasiloxane, hexamethyldisiloxane, hexamethylcyclotrisiloxane, tetramethyldisiloxane, divinyltetramethyldisiloxane, dimethyltetramethoxydisiloxane, tetraethoxydimethyldisiloxane, tetramethyldiethoxydisiloxane, and any combination thereof.

6. The process of claim 1, wherein the metal layer is comprised of a material selected from the group consisting of aluminum, steel, stainless steel, titanium, nickel, chromium, alloys thereof and a combination thereof.

7. The process of claim 1, wherein the metal layer is deposited by a thermal evaporation, sputtering, or cathodic arc method.

8. The process of claim 1, wherein the topcoat layer is a clear powder coating or liquid clear coat for providing environmental protection to the metal layer.

9. The process of claim 1, wherein said substrate is a metal object made by a method selected from the group consisting of sheet forming, casting, extrusion, weldments, wrought form, or 3D printing.

10. The process of claim 10, wherein said metal object is selected from the group consisting of iron, steel, aluminum, brass, zinc, magnesium, metal alloys and combinations thereof.

11. The process of claim 1, wherein said substrate is a plastic object produced by molding, casting, extrusion, or 3D printing or other form of fabrication, and the plastic object is comprised of a polymer selected from the group consisting of acrylonitrile-butadiene-styrene, polyvinyl chloride, polyethylene terephthalate, polybutylene terephthalate, polypropylene, polyethylene, polycarbonate, polystyrene, polyamides, acrylic or polymethyl methacrylate, and a combination thereof.

12. The process of claim 1, wherein said substrate is a carbon fiber object produced by molding, 3D printing or other form of fabrication.

13. A component comprising a decorative substrate prepared by the process of claim 1.

14. A process for metalizing a substrate, said process comprising:
a) providing a substrate;
b) cleaning or preparing a surface of the substrate, the cleaning or preparing comprising at least one alkaline cleaning step, one surface conversion step, a rinsing step, a sealing step, and a drying step;
c) applying and curing a polymeric primer layer over said cleaned or prepared surface of said substrate;
d) applying a plasma enhanced chemical vapor deposition (PECVD) layer over the polymeric primer layer to form a bonding interface layer;
e) applying a metal layer via a sputtering, cathodic arc or thermal evaporative deposition process onto the bonding interface layer; and
f) optionally applying and curing a topcoat layer over the metal layer.

15. The process of claim 14, wherein said polymeric primer layer is an organic, thermosetting liquid or powder which is cured at temperature in the range of 170 to 500° F.

16. The process of claim 14, wherein said PECVD process comprises use of a gas selected from the group consisting of argon, oxygen, hydrogen, and any combination thereof.

17. The process of claim 15, wherein said PECVD process comprises the use of an organosilicon compound.

18. The process of claim 17, the organosilicon compound selected from the group consisting of tetraethoxysiloxane, octamethylcyclotetrasiloxane, hexamethyldisiloxane tetramethyldisiloxane and combinations thereof.

19. The process of claim 14, wherein the topcoat layer comprises decorative particles as an appearance-enhancing additive to further alter the aesthetic effect of the metal layer.

20. A component comprising a finished substrate having a decorative metal finish, the finished substrate prepared by the process of claim 14.
